(19) United States
(12) Patent Application Publication
(10) Pub. No.: US 2013/0143067 A1
(43) Pub. Date: Jun. 6, 2013

(54) ANTI-OXIDATION COATING USING GRAPHENE

(71) Applicants: Ki Il KIM, Los Angeles, CA (US); Young K. Kim, Los Angeles, CA (US); Sang-Woo Kim, Suwon (KR)

(72) Inventors: Ki Il KIM, Los Angeles, CA (US); Young K. Kim, Los Angeles, CA (US); Sang-Woo Kim, Suwon (KR)

(73) Assignee: K-TECHNOLOGY USA, INC., Pica Rivera, CA (US)

(21) Appl. No.: 13/368,935

(22) Filed: Feb. 8, 2012

Related U.S. Application Data
(63) Continuation-in-part of application No. 13/311,376, filed on Dec. 5, 2011.

(51) Int. Cl. B32B 15/04; B05D 1/02; B32B 9/04; C23C 16/26; B82Y 40/00; B82Y 30/00

(52) U.S. Cl. 428/634; 428/333; 428/368; 427/249.1; 427/427; 977/734; 977/842

(57) ABSTRACT

A metal plate or wire coated with a graphene layer and a method for manufacturing the graphene coated metal plate or wire are provided. The graphene coated metal plate or wire can include a nickel layer or a copper layer coated on an outer surface of the metal plate or wire, and a graphene layer coated on an outer surface of the nickel layer or the copper layer. The graphene coated metal plate or wire can be manufactured by using a chemical vapor deposition equipment or spraying a reduced graphene oxide (RGO) solution or a graphene oxide (GO) solution on the surface.

### RELATED APPLICATIONS

This application is a Continuation-in-Part Application of Application No. 13/311,376, filed Dec. 5, 2011, entitled “A Graphene Electrical Wire And A Method For Manufacturing Thereof,” in which the entire disclosure thereof is incorporated by reference herein in its entirety.

### BACKGROUND OF THE INVENTION

1. Field of the Invention

This invention relates to a method for coating graphene on the surface of a wire using a metal wire as a catalyst via a Large Scale Graphene Synthesis in which a metal catalyst such as copper, nickel, and ruthenium is utilized. More particularly, the present invention relates to metal products coated with grapheme for anti-oxidation.

2. Description of Related Art

A conventional wire is usually made of copper which has high electrical conductivity. Copper allows current to flow easily and emit low heat due to low resistivity. Also, copper has the advantage of easy manufacturing due to its high ductility and tensile strength. Because the price of raw material has a tendency of rising, copper prices have risen from 6,299 US dollars per ton in 2009 to 10,070 US dollars per ton in 2011, and this tendency is expected to continue in the future. Also, copper wire has the disadvantage of which its diameter must be increased in order to increase proportionately the amount of electrical power that it can generate.

As the price of copper rises, interest for a new conductible material which can replace copper is growing. In terms of the electrical conductivity, aluminum cannot replace copper because of its low electrical conductivity, and gold and silver, while having a higher electrical conductivity, cannot replace copper because of their high prices.

### SUMMARY OF THE INVENTION

According to one aspect, the present invention provides a method of coating a metal catalyst layer on a fiber shape polymer, which is the core of a wire, using a coating method such as electrolysis and evaporation.

In accordance with another aspect of the present invention, a graphene electrical wire is provided that has a metal core having a shape of a fiber, and a graphene layer synthesized on the outer surface of the metal core.

In accordance with another aspect of the present invention, a method for manufacturing an electrical wire is provided. The method includes providing a metal core having the shape of a fiber, and synthesizing a graphene layer on the outer surface of the metal core.

In accordance with another aspect of the present invention, a graphene electrical wire is provided that a polymer core, a metal layer coated on the polymer core, and a graphene layer synthesized on the outer surface of the metal layer.

Also, in accordance with another aspect of the present invention, provided is a method for manufacturing an electrical wire, the method including providing a polymer core, coating a metal layer on the polymer core, and synthesizing a graphene layer on the outer surface of the metal layer.

In accordance with another aspect of the present invention, a metal plate is provided that can include a graphene layer coated on an outer surface of the metal plate to prevent oxidation.

In accordance with one embodiment of the present invention, the metal plate can include a nickel layer coated on an outer surface of the metal plate, and a graphene layer coated on an outer surface of the nickel layer.

In accordance with another embodiment of the present invention, the metal plate can include a copper layer coated on an outer surface of the metal plate, and a graphene layer coated on an outer surface of the copper layer. Also, the metal plate can be one of, a steel plate, a stainless plate, an aluminum plate, or a combination thereof.

In accordance with another aspect of the present invention, a metal wire is provided that can include a metal core having a shape of fiber, and a graphene layer synthesized on an outer surface of the metal core to prevent oxidation. The metal core can be one of, a steel core, a stainless core, an aluminum core, or a combination thereof. Further, the metal wire can be an electrical wire.

In accordance with another aspect of the present invention, a method is provided for coating a graphene layer on a metal plate that can include synthesizing the graphene layer to prevent oxidation by using a chemical vapor deposition equipment.

In accordance with another aspect of the present invention, a method is provided for coating a graphene layer on a metal plate that can include spraying one of, a reduced graphene oxide (RGO) solution or a graphene oxide (GO) solution, on an outer surface of the metal plate.

In accordance with another aspect of the present invention, a method is provided for coating a graphene layer on a metal plate that can include coating one of, a nickel layer or a copper layer, on the metal plate, and spraying one of, a reduced graphene oxide (RGO) solution or a graphene oxide (GO) solution, on an outer surface of one of, the nickel layer or the copper layer.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 illustrates a graphene electrical wire including a fiber shape metal core made of one of, copper (Cu), nickel (Ni), and ruthenium (Ru), and a graphene layer synthesized on the outer surface of the metal core according to one embodiment of the present invention;

FIG. 2 illustrates a graphene electrical wire comprising a polymer core, a metal layer coated on the polymer core, and a graphene layer synthesized on the outer surface of the metal layer according to another embodiment of the present invention; and

FIG. 3 illustrates a metal plate coated with graphene.

### DETAILED DESCRIPTION

Exemplary embodiments now will be described more fully hereinafter with reference to the accompanying drawings, in which exemplary embodiments are shown. This disclosure may, however, be embodied in many different forms and should not be construed as limited to the exemplary embodiments set forth therein. Rather, these exemplary embodiments are provided so that this disclosure will be thorough and complete, and will fully convey the scope of this disclosure to those skilled in the art. In the description, details of well-known features and techniques may be omitted to avoid unnecessarily obscuring the presented embodiments. In the drawings, like reference numerals in the drawings denote like elements. The shape, size and regions, and the like, of the drawing may be exaggerated for clarity.

According to one aspect of the present invention, a graphene electrical wire includes a metal core having the shape of a fiber, and a graphene layer synthesized on the outer surface of the metal core.

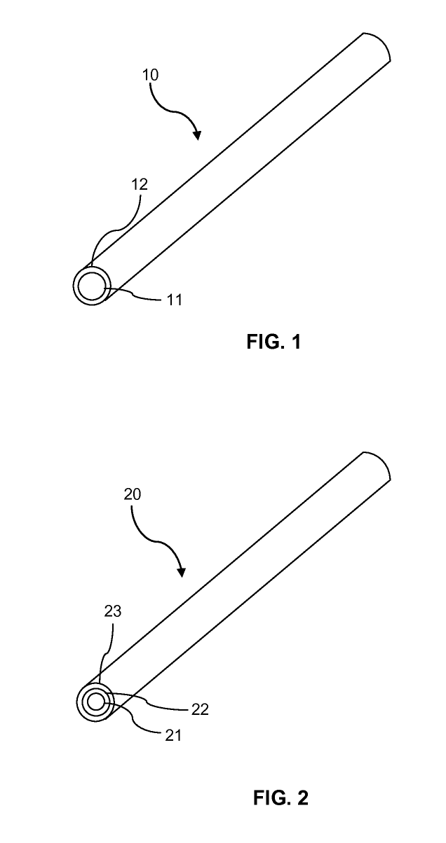

FIG. 1 illustrates a graphene electrical wire 10 according to one aspect of the present invention. The graphene electrical wire 10 can include a metal core 11 having the shape of a fiber, and a graphene layer 12 synthesized on the outer surface of the metal core 11. The metal core 11 can be made of one of, copper (Cu), nickel (Ni), and ruthenium (Ru).

The graphene layer 12 can be synthesized by Chemical Vapor Deposition or Large Scale Graphene Synthesis. The Large Scale Graphene Synthesis became possible using copper as a catalyst since professor Ruoff at the UC Texas at Austin published a relevant thesis (see Xuesong Li et al., “Large-Area Synthesis of High-Quality and Uniform Graphene Films on Copper Foils,” Science, 5 Jun. 2009: 1312-1314). Also, professor Tumor at Rice University succeeded the Large Scale Graphene Synthesis using a polymer solid source with a copper catalyst (see Sun et. al., “Growth of Graphene from Solid Carbon Sources. Nature Letters.” Vol. 468, 2010: 549-552).

In another exemplary embodiment of the present invention, the graphene layer 12 can be produced by exfoliation.

According to another aspect of the present invention, a graphene electrical wire can include a polymer core, a metal layer coated on the outer surface of the polymer core, and a graphene layer synthesized on the outer surface of the metal layer.

FIG. 2 illustrates a graphene electrical wire 20 according to one aspect of the present invention. Referring to FIG. 2, the graphene electrical wire 20 can include a polymer core 21, a metal layer 22 coated on the outer surface of the polymer core 21, and a graphene layer 23 synthesized on the outer surface of the metal layer 22. The metal layer 22 can be made of one of, copper (Cu), nickel (Ni), and ruthenium (Ru). The graphene layer 23 can be synthesized by chemical vapor deposition, or can be produced by exfoliation.

By using the graphene having 100 times the current density of copper, high heat conductivity, and chemical resistance, it is possible to manufacture an electrical wire which is thin, but having high electrical conductivity. As the thickness of wire is reduced, the amount of copper decreases, and thus, the economic loss can be reduced due to increasing global copper prices.

Also, graphene electrical wire can be used to protect the environment by reducing the usage of copper, which is a mineral, because this electrical wire utilizes polymer or graphene, both of which are organic materials. Also, an added benefit is that graphene wire can be used to reduce the manufacturing cost of existing electrical wires while allow efficient electrical supply due to its high current density. Further, the graphene electrical wire can be used to prevent oxidation.

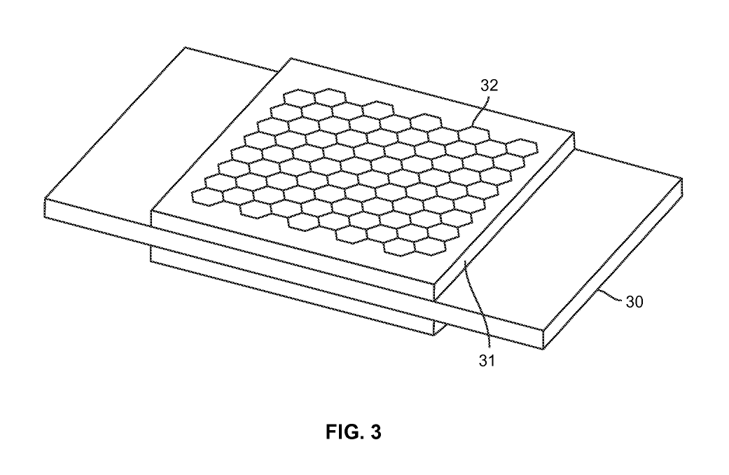

FIG. 3 illustrates a metal plate 30 coated with a nickel or copper layer 31, and then with a graphene layer 32. After the metal plate 30 is cleansed and preprocessed in a vacuum chamber, the nickel or copper layer 31 can be synthesized on the surfaces of the metal plate 30. Further, the graphene coated metal plate 30 can be manufactured by finishing graphene synthesis on the surfaces (both sides) of the nickel or copper coated metal plate.

As an exemplary embodiment of the present invention, the graphene layer 32 can be synthesized by using a chemical vapor deposition (CVD) equipment, in which the graphene layer 32 is directly deposited on the surface of the nickel or copper layer 31, which is a catalyst layer.

As another exemplary embodiment of the present invention, the graphene layer 32 can be formed by spraying a reduced graphene oxide (RGO) or graphene oxide (GO) solution (i.e., graphene ink) on the surfaces of the metal plate 30 or on the surfaces of the nickel or copper layer 31. Any metal including steel, stainless, aluminum, and alloys can be coated with the graphene layer 32.

One advantage of the present invention is that it creates a thinner and more transparent anti-oxidation coating compared to an existing anti-oxidation coating known in the art. Also, the graphene layer 32 which provides anti-oxidation can be synthesized on the surfaces of not only ordinary flat metal plates but also on other products with curved surfaces.

Although exemplary embodiments of the present invention have been described in detail hereinabove, it should be clearly understood that many variations and modifications of the basic inventive concepts herein taught which may appear to those skilled in the present art will still fall within the spirit and scope of the present invention, as defined in the appended claims.

What is claimed is:

1. A metal plate comprising:
a graphene layer to prevent oxidation.

2. The metal plate of claim 1, further comprising:
a nickel layer coated on an outer surface of the metal plate, wherein the graphene layer is coated on an outer surface of the nickel layer.

3. The metal plate of claim 1, further comprising:
a copper layer coated on an outer surface of the metal plate, wherein the graphene layer is coated on an outer surface of the copper layer.

4. The metal plate of claim 1, wherein the metal plate is one of, a steel plate, a stainless plate, an aluminum plate, or a combination thereof.

5. A metal wire comprising:
a metal core having a shape of fiber; and
a graphene layer synthesized on an outer surface of the metal core to prevent oxidation.

6. The metal wire of claim 5, wherein the metal core is one of, a steel core, a stainless core, an aluminum core, or a combination thereof.

7. The metal wire of claim 5, wherein the metal wire is an electrical wire.

8. A method for coating a graphene layer on a metal plate to prevent oxidation, the method comprising depositing graphene to form the graphene layer onto the metal plate by using a chemical vapor deposition equipment.

9. The method of claim 8, wherein the metal plate is one of, a steel plate, a stainless plate, an aluminum plate, or a combination thereof.

10. A method for coating a graphene layer on a metal plate to prevent oxidation, the method comprising spraying one of, a reduced graphene oxide (RGO) solution, or a graphene oxide (GO) solution on an outer surface of the metal plate.

11. The method of claim 10, wherein the metal plate is one of, a steel plate, a stainless plate, an aluminum plate, or a combination thereof.

12. A method for coating a graphene layer on a metal plate to prevent oxidation, the method comprising:
coating one of, a nickel layer or a copper layer, on the metal plate; and
one of, (1) spraying one of, a reduced graphene oxide (RGO) solution or a graphene oxide (GO) solution, on an outer surface of the one of, the nickel layer or the copper layer, or (2) depositing graphene to form the graphene layer on the outer surface of the one of, the nickel layer or the copper layer by using a chemical vapor deposition equipment.

13. The method of claim 12, wherein the metal plate is one of, a steel plate, a stainless plate, an aluminum plate, or a combination thereof.
